(19) United States
(12) Patent Application Publication
(10) Pub. No.: US 2016/0230295 A1
(43) Pub. Date: Aug. 11, 2016

(54) Method for Electrocatalytic Reduction using Au Nanoparticles Tuned or Optimized for Reduction of CO2 to CO

(71) Applicant: Brown University, Providence, RI (US)

(72) Inventors: Shouheng Sun, East Greenwich, RI (US); Andrew Peterson, Providence, RI (US); Wenlei Zhu, Providence, RI (US); Ronald Michalsky, Wadenswil (CH)

(73) Assignee: Brown University, Providence, RI (US)

(21) Appl. No.: 15/099,691

(22) Filed: Apr. 15, 2016

Related U.S. Application Data
(63) Continuation of application No. PCT/US2014/060818, filed on Oct. 16, 2014.
(60) Provisional application No. 61/891,690, filed on Oct. 16, 2013.

(51) Int. Cl. C25B 11/04; C30B 29/02; C25B 1/00

(52) U.S. Cl. CPC C25B 11/0473; C25B 1/00; C25B 11/0405; C25B 11/0415; C30B 29/02

(57) ABSTRACT

Selective electrocatalytic reduction of carbon dioxide (CO₂) to carbon monoxide (CO) on gold (Au) nanoparticles (NPs) in 0.5 M KHCO₃ at 25° C. Among monodisperse 4-, 6-, 8-, and 10-nm NPs tested, the 8 nm Au NPs show the maximum Faradaic efficiency (FE), up to 90% at −0.67 V vs. reversible hydrogen electrode. Density functional theory (DFT) calculations suggest that edge sites dominate over corner sites on the Au NP surface facilitating stabilization of the reduction intermediates, such as COOH1*, and the formation of CO. This mechanism is further supported by the fact that Au NPs embedded in a matrix of butyl-3methylimidazolium hexafluorophosphate for more efficient COOH* stabilization exhibit even higher reaction activity (3 A/g mass activity) and selectivity (97% FE) at −0.52 V (vs. RHE). Use of monodisperse Au NPs to optimize the available reaction intermediate binding sites thus allows efficient and selective electrocatalytic reduction of CO₂ to CO.

### RELATED APPLICATIONS

The present application is a continuation of and claims the benefit of international application serial number PCT/US2014/060818 filed Oct. 16, 2014, which claims the benefit of U.S. provisional application Ser. No. 61/891,960 filed Oct. 16, 2013, each of which is hereby incorporated herein by reference in its entirety.

### GOVERNMENT SUPPORT

This invention was made with government support under grant CHE1240020 awarded by the National Science Foundation and grant N00014-12-1-0851 awarded by the Office of Naval Research. The government has certain rights in the invention.

### TECHNICAL FIELD

The invention field relates to electrocatalytic conversion and to processes for reducing emissions of carbon dioxide into the atmosphere.

### BACKGROUND

It is generally accepted that atmospheric carbon dioxide (CO₂) is a greenhouse gas that the planet currently has in excess, is extremely stable, and that the current rates of generating additional carbon dioxide should be reduced or controlled. One approach to such control involves injecting the CO₂ produced by an industrial process into a subterranean well that prevents it from reaching the atmosphere; another may rely on a chemically stable capture of the CO₂ in a mineral species. Other methods potentially involve converting or recycling the CO₂ into a different carbon compound such as an organic acid or carbon monoxide (CO) to use as a feedstock for other chemical syntheses. However conversion of carbon dioxide into carbon monoxide has in the past been performed chemically only at great expense. A less expensive and more convenient and energy-efficient process for such CO₂ reduction would therefore be desirable.

Some perspective may be gained by considering that the ever-increasing worldwide consumption of fossil fuels for energy and chemical applications has accelerated the depletion of these finite natural resources and led to over-production of the greenhouse gas carbon dioxide (CO₂) (Goeppert, A. et al., Am. Chem. Soc. 2011, 133, 20164). To meet the world's fuel and chemical demands in a sustainable way, the overly produced CO₂ could perhaps be converted into reusable carbon forms (Graves, C. et al. Renewable Sustainable Energy Rev. 2011, 15,1). Among many different approaches developed thus far for CO₂ reactivation, electrochemical reduction of CO2 is considered a potentially “clean” method, as the reduction may proceed at the expense of a sustainable supply of electric energy (Whipple, D. T. et al. J. Phys. Chem. Lett. 2010, 1, 345). Theoretically, CO₂ can be reduced in a neutral aqueous solution (pH=7, 1 M electrolyte at 25° C. and 1 atm CO₂) to form carbon monoxide (CO), formic acid (HCO₂H), methanol (CH₃OH), methane (CH₄), ethylene (C₂H₄) or other hydrocarbons, at potentials around +0.2 to −0.2 V (vs. reversible hydrogen electrode, RHE) (Benson, E. E. et al. Chem. Soc. Rev. 2009, 38, 89). Experimentally, however, very negative potentials must be applied to initiate CO₂ reduction (Benson et al., supra). These large over-potentials not only consume more electrical energy but also promote the uncontrolled formation of competitive reduction products, such as hydrogen (H₂), causing the reaction to have low energetic efficiencies and poor selectivity (Costentin, C. et al. Chem. Soc. Rev. 2013, 42, 2423; Gattrell, M. et al. Electroanal. Chem. 2006, 594,1).

To succeed in CO₂ reduction and conversion, highly efficient catalysts must be developed to lower the CO₂ reduction over-potentials and to control the energy pathways of reaction intermediates. Various metal electrocatalysts have been screened experimentally (De Jesus-Cardona, H. et al. Electroanal. Chem. 2001, 513, 45; Innocent, B. et al. J. Appl. Electrochem. 2009, 39, 227; Chen, Y. H. et al. J. Am. Chem. Soc. 2012, 134, 1986; Jitaru, M. et al. J. Appl. Electrochem. 1997, 27, 875; Noda, H. et al. Bull. Chem. Soc. Jpn. 1990, 63, 2459; Hori, Y. et al. J. Chem. Soc., Chem. Commun. 1987, 728) and analyzed computationally (Peterson, A. A et al. J. Phys. Chem. Lett. 2012, 3, 251; Peterson, A. A. et al. Energy Environ. Sci. 2010, 3, 1311; Durand, W. J. et al. Surf. Sci. 2011, 605, 1354) to rationalize their activity and selectivity for CO₂ reduction. Recent advances in the synthesis of nanoparticles (NPs) allow for testing of potentially increased reaction kinetics due to the controlled surface area and surface morphology achievable in fabrication of NPs. This is demonstrated by electrochemical reduction of CO, into hydrocarbons on Cu, or reduction into CO on Au-based NPs/clusters (Chen, Y. H. et al. J. Am. Chem. Soc. 2012, 134, 19969; Xu, Z. C. et al. Chem. Commun. 2012, 48, 5626; Kauffman, D. R. et al. J. Am. Chem. Soc. 2012, 134, 10237). Recently, a new form of Au nanostructured catalyst made by anodization and electroreduction of an Au electrode has been demonstrated to show high selectivity for catalyzing CO₂ reduction to CO with current densities between 2 to 4 mA/cm² and Faradaic efficiencies (FE) around 96% at −0.35 V (vs. RHE) (Chen, Y. H. et al, supra). It is believed that the increased stabilization of the reduced CO₂ radical or the reaction-intermediate COOH* and the weakened CO binding on the Au surface contribute to this selective reduction of CO₂ to CO (Chen, Y. H. et al., supra; Kauffman, D. R. et al., supra). However, the structure features of the catalyst surface are difficult to characterize, a factor that complicates further catalyst optimization.

### SUMMARY

An embodiment of the invention provides a process for electrocatalytic reduction of CO₂ to CO in which the reduction is catalyzed by gold nanoparticles on a conductive support, and the nanoparticles are sized to present a surface structure for efficient CO₂ reduction.

For example, the nanoparticles are tuned to present a crystalline structure in which the nanoparticles, have a lower amount of hydrogen-evolving crystal corner sites and greater amount of CO-converting edge sites, so as to constitute a clean CO₂ conversion medium with low formation of undesired by-product species.

In an embodiment of the process, the conductive support is Ketjen carbon.

In another embodiment of the process, the gold nanoparticles are formed with a diameter less than 10 nm to tune the catalytic activity of the particles. For example, the gold nanoparticles are formed with a diameter of approximately 8 nm.

An embodiment of the invention is a method in which the reduction is performed in alkaline solution.

An embodiment of the invention provides a catalyst that includes gold nanoparticles of approximately 8 nm diameter for use in electrocatalytic reduction of carbon dioxide to carbon monoxide.

An embodiment of the invention provides a catalyst that contains gold nanoparticles of a cuboctahedral crystalline configuration of a size to present CO₂-converting edge sites with relatively fewer hydrogen-evolving corner sites, resulting in a clean CO₂ conversion medium with low formation of by-product.

### BRIEF DESCRIPTION OF THE DRAWINGS

These and other features of the invention will be understood from the description and claims herein, taken together with the drawings, wherein:

FIG. 1a shows TEM images of 8 nm gold nanoparticles;

FIG. 1b shows the nanoparticles of FIG. 1a on a carbon support (C—Au NPs);

FIG. 1c shows a graph of potential-dependent Faraday efficiency (FE) of the carbon C—Au NPs of FIGURE lb for electrocatalytic reduction of CO₂ to CO; and

FIG. 1d shows current densities for CO formation (indicative of mass activity) on a carbon-gold catalytic electrode at various potentials;

FIGS. 2a and 2b show free energy diagrams for electrochemical reduction of CO₂ to CO and of protons to hydrogen on Au(111), Au(211) of a 13-atom Au cluster at −0.11 V, calculated from the experiments reported herein, and also from literature data converted to free energies;

FIG. 3 plots the density of adsorption sites by type ((111), (001), edge, or corner on-top sites) on closed shell cuboctahedra Au clusters vs. cluster diameter, and also shows the weight fraction of Au bulk atoms (grey dots); data points for clusters of 13, 55, 147 and 1415 Au atoms are identified in the FIGURE;

FIGS. 4a and 4b show potential dependent faraday efficiencies and mass activities of C—Au-Ionic Liquid (IL) on the electrocatalytic reduction of CO₂ to CO in the presence of 10 μL IL;

FIG. 4c is a plot of mass current densities over time of the C—Au-IL (8 nm NPs) and 10 μIL for CO₂ reduction; and

FIG. 4d shows a TEM image of the 8 nm NPs in C—Au-IL after the CO₂ reduction reaction study.

### DETAILED DESCRIPTION

Considering the size effect commonly observed in NPs and the promising results demonstrated from nanostructured Au, Applicants determined to study monodisperse Au NPs as a catalyst for electrochemical reduction of CO₂ in 0.5 M KHCO3 (pH 7.3) at room temperature. Applicants screened 4-, 6-, 8-, and 10-nm Au NPs and found that the 8 nm Au NPs were especially active for CO₂ reduction into CO. Using density functional theory (DFT) calculations, Applicants hypothesized that this enhanced activity and selectivity is due to the presence of dominant edge sites on the 8 nm NP surface, which facilitate the adsorption/stabilization of key reaction intermediates (such as COOH*) involved in the CO₂ reduction into CO, and which inhibits the hydrogen evolution reaction (HER). This reaction model gained further support experimentally as Au NPs embedded in a matrix of butyl-3-methylimidazolium hexafluorophosphate, a more efficient COOH* stabilizer, were indeed found to be more active and selective for CO₂ reduction into CO. The composite catalyst containing 8 nm NPs exhibited up to 97% Faraday efficiency (FE) towards CO and a mass activity of 3 A/g at −0.52 V. The work reported herein demonstrates great potential of tuning electrocatalysis of Au NPs for diverse reactions, in particular by creating optimal edge sides on the surface of NPs of controlled size for more effective CO₂ reduction into CO. The reduction process as described herein is being published as “Monodisperse Au Nanoparticles for Selective Electrocatalytic Reduction of CO₂ to CO” by co-authors Wenlei Zhu, Ronald Michalsky, Onder metin, Haifeng Lv, Shaojun guo, Christopher Wright, Xiaolian Sun, Andrew A. Peterson and Shouheng Sun, in J. Am. Chem. Soc. 2013, 135, 16833-16836, to which reference may be made for further details and review of the supporting information regarding electrocatalytic properties described herein and associated content. The publications mentioned and material from these publications are incorporated herein by reference, to the extent such supporting information may be deemed useful.

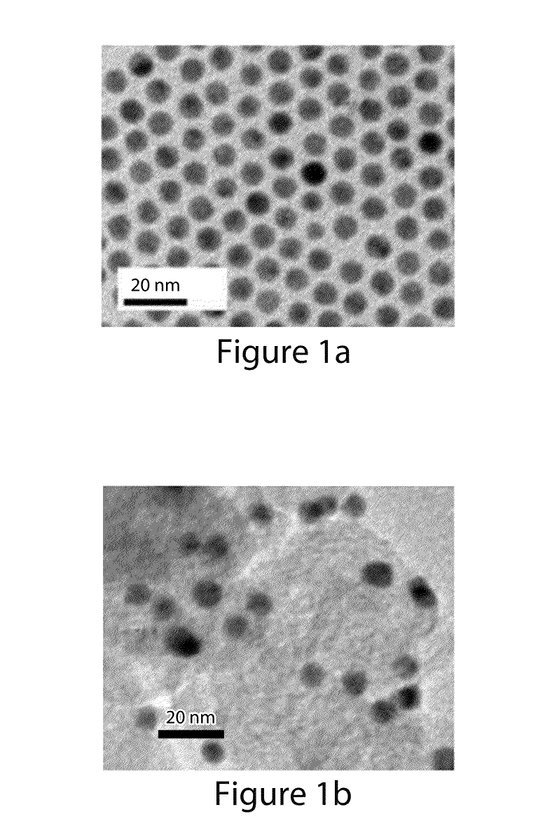

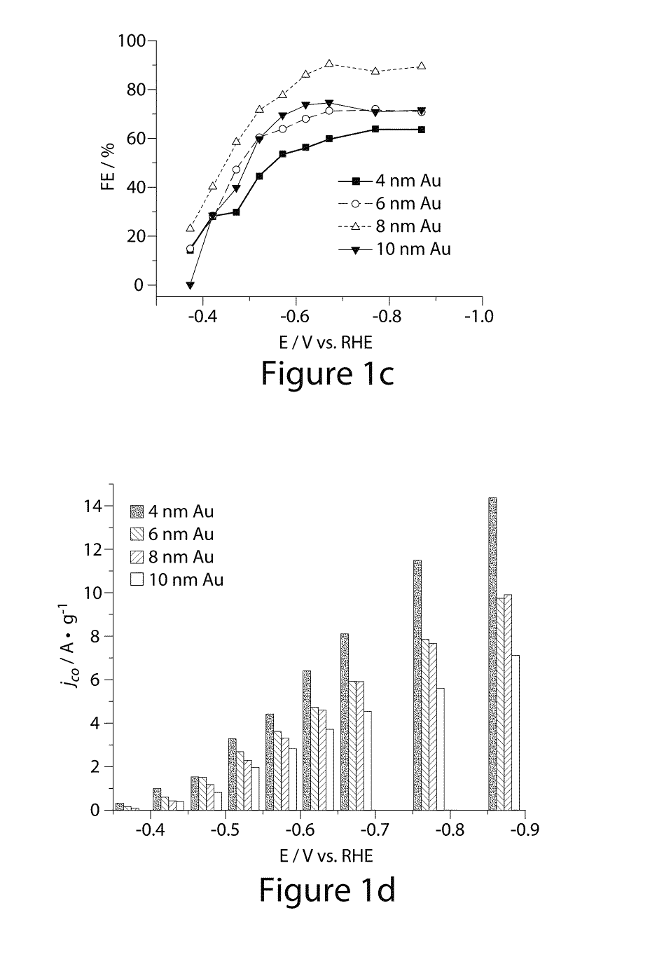

Monodisperse 4-, 6-, 8- and 10 nm Au NPs were prepared by procedures described in Lee, Y. et al. Chem. Mater. 2010, 22, 755; Peng, S. et al. Nano Res. 2008, 1, 229; Lee, Y. M. et al. Angew. Chem., Int. Ed. 2010, 49, 1271. FIG. 1a shows a transmission electron microscopy (TEM) image of the 8 nm diameter particles which will now be discussed in greater detail. TEM images of the 4-, 6- and 10 nm NPs (found to be sub-optimal and thus not detailed herein) may be found in FIGS. S1a-c of the Supporting Information for the published report, in J. Am. Chem. Soc. 2013, 135, 16833-16836, which is hereinafter referred to as simply “Supporting Information”. The average diameters of the different size polyhedral NPs are 7.7±0.3 nm (FIG. 1a), 4.1±0.3 nm, 6.3+0.3 nm, and 10.5±0.5 nm (FIG. S1a-c). The Supporting Information also shows X-ray diffraction (XRD) patterns of the Au NPs (FIG. S2). Using Schema's formula, we analyzed the line broadening of the 4-, 6-, 8-, and 10-nm Au(111) peaks and estimated the average crystal diameters of the NPs to be 2.0-, 2.3-, 4.0-, and 5.9-nm respectively, which are all smaller than the particle diameters estimated from TEM analysis, indicating a polycrystalline nature of the Au NPs.

The Au NPs were deposited on Ketjen carbon support (Kejen EC300J) at a weight ratio of 1:1, and annealed in air for 8 h at 165° C. to remove the organic surfactant as reported in Metin, O. et al. Nanoscale 2013, 5, 910 and Li, D. G. et al. ACS Catal. 2012, 2, 1358, giving C—Au. TEM analyses of the C—Au showed no NP morphological changes or aggregation after the treatment (FIG. 1b). The Au weight ratios in the C—Au catalysts were measured by inductively coupled plasma atomic emission spectroscopy (ICP-AES) to be 0.21, 0.28, 0.32, 0.35 g Au per gram of C-Au for the 4-, 6-, 8-, and 10-nm Au NPs respectively.

To study electrocatalytic reduction of CO₂ on the C—Au catalyst, a C—Au paste was first prepared by grinding 20 mg of C—Au NPs and 3 mg of polyvinylidene fluoride (PVDF, 15% wt) followed by addition of a few drops of N-methyl-2-pyrrolidone (NMP) (see the Supporting Information). The C—Au-PVDF paste was then painted onto the carbon paper (Toray TGP-H-060)—see Mu, J. B. et al. Nanoscale 2011, 3, 5034 and Ravikumar, R. et al. Phys. Chem. Chem. Phys. 2013, 15, 3712, and dried under vacuum to serve as working electrodes.

The electrocatalysis was performed in a conventional two-compartment H-cell (separated by a Nafion membrane) containing 60 ml of 0.5 M KHCO₃ solution (pH 7.3). At the reported reduction conditions, CO and H₂ were the only two detectable reaction products with net FE at 100.6%±3.9%. FIG. 1c shows the potential-dependent FE's of different C—Au NPs for CO formation. Significant amounts of CO are generated at an onset potential of −0.37 V, which is 0.26 V below the theoretical equilibrium potential (about −0.11 V). FE increases when more negative potentials are applied and reaches near saturation at −0.65 V. The CO2 reduction activity is Au NP size-dependent, and the 8 nm NPs were found to be the most active for CO formation with FE reaching 90% at −0.67 V, which is better than other polycrystalline Au catalysts (87% FE at −0.74 V) reported previously (Tang, W. et al. Phys. Chem. Chem. Phys. 2012, 14, 76). FIG. 1d summarizes the mass activities of the Au NPs at different reduction potentials. The 4 nm Au NPs have the highest value due to their small size and large surface area.

Electrochemical reduction of CO₂ to CO in an aqueous solution depends on the energetic stabilization of CO₂ reduction intermediates by catalytically active surfaces Peterson, A. A et al. J. Phys. Chem. Lett., supra and Peterson, A. A. et al. Energy Environ. Sci., supra; Hansen, H. A. et al. J. Phys. Chem. Lett. 2013, 4, 388).

The reaction can be summarized with the following steps:

CO₂(g)+H⁺(aq)+e⁻+*→COOH* (1)

COOH*+H⁺(aq)+e⁻→CO*+H₂O(1) (2)

CO*→CO(g)+* *3)

H⁺(aq)+e⁻+*→H* (4)

H*+H⁺(aq)+e⁻→H₂+* (5a)

where the asterisk denotes either a surface-bound species or a vacant catalytically active site. The formation of CO depends not only on the stabilization step (1) and the reduction step (2) of a COOH*, but also on the ability of the catalyst to liberate the CO product, step (3). For high CO selectivity, the catalyst needs to balance steps 1-3 while inhibiting the hydrogen evolution reaction (HER) via H⁺ reduction of steps (4)-(5), a major side reaction that is often observed in studying electrochemical reduction of CO₂.

To understand the origin of the high CO selectivity of the Au NPs, we applied density functional theory (DFT) to calculate the free energies of these five elementary reaction steps. The catalyst was modeled in a number of different geometries with the Grid-based projector-augmented wave (GPAW) electronic-structure code in order to understand the reactivity of different Au features. The method of calculation is further described and may be found in the Supporting Information. The total energy of these surfaces or clusters with or without adsorbates was calculated and converted to free energy (ΔG) at 25° C., 1 atm and −0.11 V, the theoretical equilibrium potential of CO₂ reduction into CO.

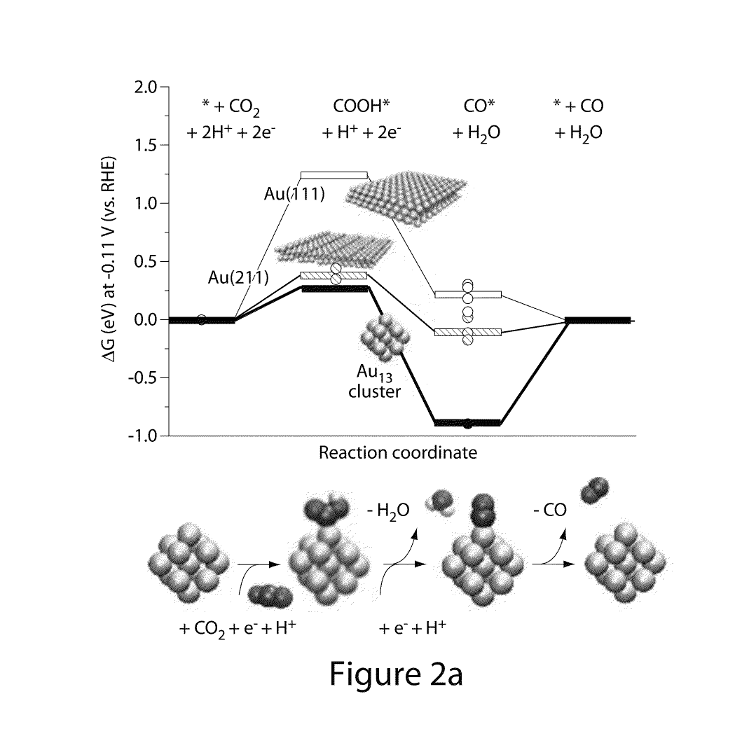

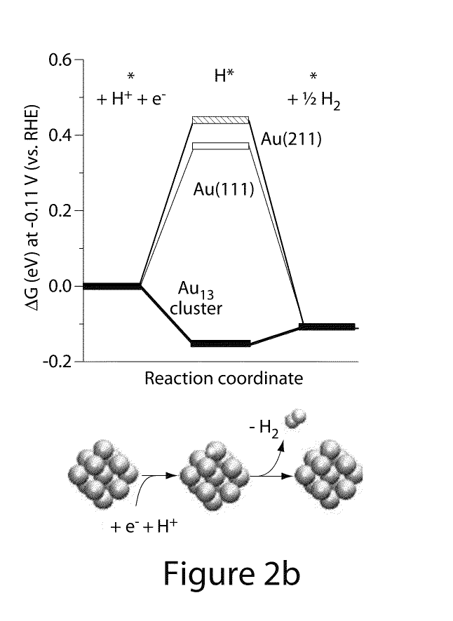

FIG. 2a shows the calculated free energy diagram for CO₂ reduction on Au(111), Au(211) and Au13, based on the computational hydrogen electrode model as in reference (Nørskov, J. K. et al. J. Phys. Chem. B 2004, 108, 17886). The literature data shown for comparison (dots and the related bar as the arithmetic average) are taken from Au(111) (Peterson, A. A. et al. Top. Catal. 2012, 55, 1276; Rodriguez, P. et al. Angew. Chem., Int. Ed. 2010, 49, 1241; Lin, C. H. et al. J. Phys. Chem. C 2011, 115, 18582; Jiang, T. et al. J. Phys. Chem. C 2009, 113, 10548; Falsig, H. et al. Angew. Chem., Int. Ed. 2008, 47, 4835), Au(211) (Peterson, A. A et al. J. Phys. Chem. Lett., supra; Hansen, H. A. et al., supra.; Peterson, A. A. et al. Top. Catal. supra; Jiang, T. et al., supra), Au13 (Peterson, A. A. et al. Top. Catal. supra) or Au12 (Jiang, T. et al., supra) and are converted to the same reference energies. All energies are plotted at the reversible potential of the CO₂ to CO reaction and a “perfect” catalyst would exhibit zero free energy change throughout the reaction. On Au(111) at −0.11 V, CO₂ activation through COOH formation is associated with a high increase in free energy, ΔG. This energy can be supplied in the form of the overpotential required to form reaction intermediates. On Au(211), the required ΔG for forming the COOH intermediate is significantly lower, compared to Au(111), suggesting a higher activity of stepped surfaces in CO₂ reduction. On Au13, COOH formation is slightly more facile than on Au(211); however, the Au13 tends to over-bind CO, relative to Au(211), which would be expected to decrease the rate of product liberation. It should be noted that the effect of adsorbate coverage (¼ to 1/16 of a monolayer) does not alter the relative positions of the free energy levels significantly (Peterson, A. A et al. J. Phys. Chem. Lett., supra, Hansen, H. A. et al., supra; Peterson, A. A. et al. Top. Catal. supra; Rodriguez, P. et al., supra; Lin, C. H. et al., supra; Jiang, T. et al., supra; Falsig, H. et al., supra).

The calculated ΔG diagram suggests that the over-potential of CO₂ reduction or the partial current of CO formation on Au NPs at a given potential can be controlled by the density of catalytically active edges, which is controllable by NP size and surface structure. Similar trends can be seen with the calculated ΔG changes of adsorbed hydrogen on Au(111), Au(211), and the Au13 cluster (FIG. 2b). Au surfaces tend to be poor at the hydrogen evolution reaction due to the metal's nobility (Greeley, J. et al. Nat. Mater. 2006, 5, 909). However, the increased affinity of low-coordination sites for H, exhibited by the Au13 cluster, turns Au into a much more optimal hydrogen evolution catalyst. The ΔG of H* on the Au13 cluster is below the ΔG of COOH*, indicating formation of H2 at relative low potentials on the Au13 cluster. The Au(211) facet, on the other hand, is expected to yield high CO selectivity due to low binding energies of H* relative to COOH* on this facet. Edge sites favor CO formation while corner sites are active for H₂ evolution.

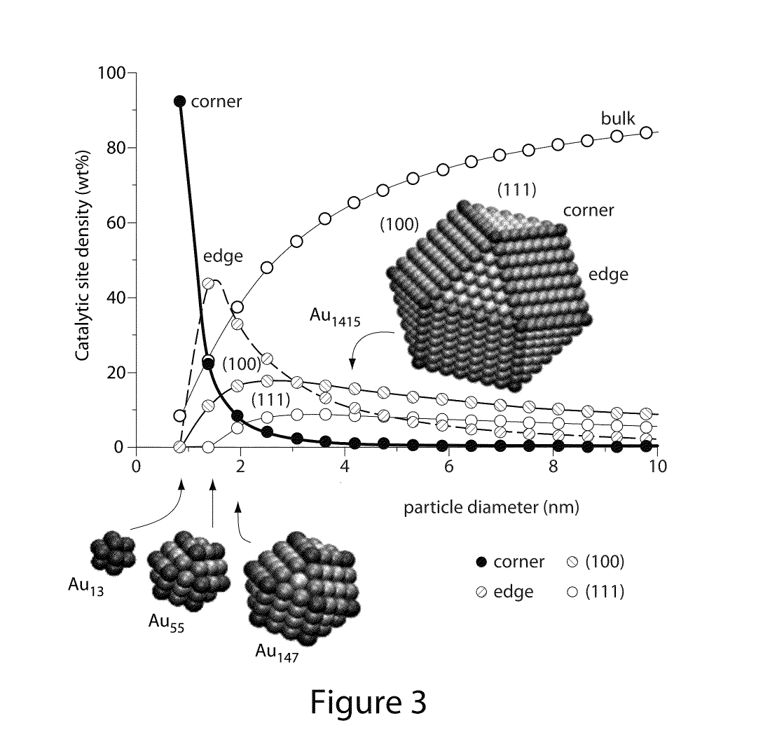

To address size-dependent electrocatalytic properties of the gold NPs, we treated the NPs as perfect cuboctahedra and obtained the relationship between the density of catalytically active surface sites and the cluster diameter (FIG. 3). At a diameter of about 2.7 nm, the fraction of the active surface atoms equals the fraction of bulk atoms, suggesting that smaller particles will have higher mass activities. NPs below this size may additionally be expected to show finite size effects (Peterson, A. A. et al. Top. Catal. supra; Qian, H. F. et al. Acc. Chem. Res. 2012, 45, 1470; Kleis, J. et al. Catal. Lett. 2011, 141, 1067). The density of strongly binding corner sites decreases to below 1% when the NP diameter is increased from 3.6 to 4.2 nm. These NPs maintain a relatively high density of edge sites between 10-13%. Our data on FE for CO formation (FIG. 1c) suggest that the origin of the activity of the Au NPs lies not in a particular quantum size effect but in an optimal density of catalytically active edge sites. The 8 nm Au NPs with 4 nm crystallite diameter appear to provide a near-optimum number of edge sites that are particularly active for CO₂ reduction into CO while minimizing the number of corner sites active for the HER.

The ΔG diagram of the CO₂ reduction into CO shows that the major fraction of the overpotential comes from the need to energetically stabilize COOH* (FIG. 2). A recent report suggests that ionic liquids (ILs) such as butyl-3methylimidazolium hexafluorophosphate (BMIM-PF6) may lower the overpotential for CO evolution (Rosen, B. A. et al. Science 2011, 334, 643) which we hypothesize may be due to the stabilization of the adsorbed COOH* intermediate. This indicates that combining C—Au NPs with IL (C—Au-IL) may allow for highly selective and active CO₂ reduction into CO.

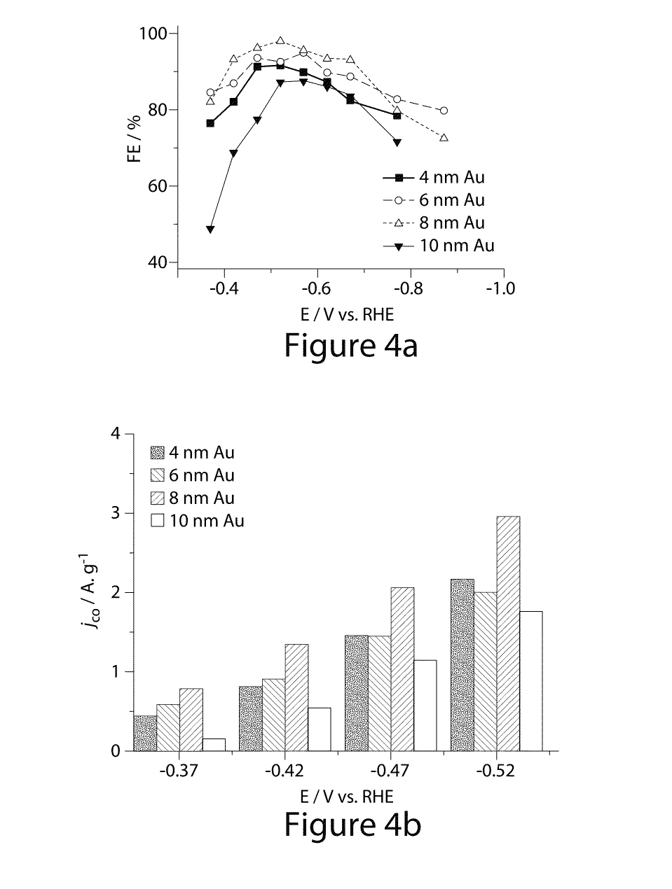

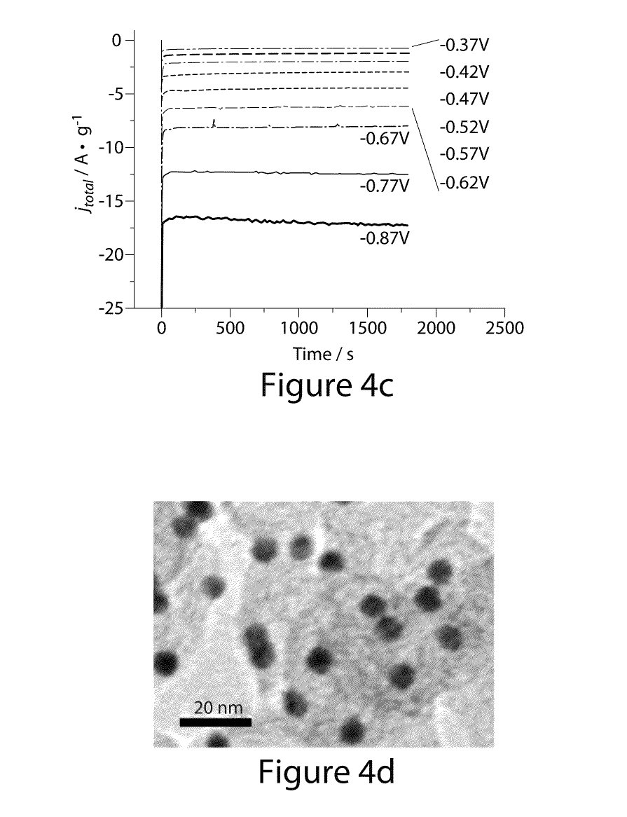

To test this hypothesis, we prepared C—Au-IL by adding IL to C—Au-PVDF paste containing 20 mg of C—Au NPs catalyst and painted the new paste onto carbon paper. The IL effect on CO₂ reduction was further studied by mixing 20 mg of the C—Au (8 nm Au NPs) with different volumes of IL. FIG. S3 of the Supporting Information shows the FE's and mass activities for CO formation in the presence of 5-, 10-, 15- or 20-μl IL. The addition of IL increases the FE significantly in the low potential region. In the region more negative than −0.6 V, both FE's and mass activities decrease sharply with increased IL loadings. This is likely caused by the potential-induced stronger adsorption of hydrophobic IL, which reduces the active sites and inhibits protonation of the reduced CO₂. For 20 mg of the C—Au, 10 μl IL is the optimum amount that can be used to enhance Au catalysis. FIGS. 4a and 4b show the activity of the C—Au-IL (10 μl IL) for reduction of CO₂ to CO. Comparing to the FE and mass activities of the C—Au NPs (FIGS. 1c and 1d), one sees that in the presence of 10 μl IL, the same 8 nm Au NPs show much higher selectivity (˜80% FE at −0.37 V and 97% FE at −0.52V) and highest mass activities for CO formation at all potential range. Both C—Au and C—Au-IL retain their catalytic activities in a wide potential region (FIG. 4c, and FIG. S4 of the Supplemental Information) and the Au NPs in the C—Au-IL show no morphological change after CO₂ reduction (FIG. 4d), indicating the C—Au NPs are stable in the current electrochemical reaction condition.

In summary, we have synthesized a series of monodisperse Au NPs and studied their electrocatalytic reduction of CO₂ to CO. Among the 4-, 6-, 8- and 10-nm Au NPs tested, the 8 nm Au NPs show the highest selectivity with their FE reaching 90% at −0.67 V. DFT calculations suggest that the highly selective CO formation on the 8 nm Au NPs is due to the presence of optimum ratio of the edge sites, which are active for CO₂ reduction, over corner sites, which are active for H₂ evolution. When embedded in a matrix of butyl-3-methylimidazolium hexafluorophosphate, the Au NPs become even more active for CO₂ reduction. The composite catalyst containing 8 nm Au NPs has FE up to 97% and mass activity of about 3 A/g at −0.52 V. Our study proves that effective stabilization of COOH* is key to the CO₂ reduction activity enhancement, and demonstrates great potentials of monodisperse Au NPs for the selective electrochemical reduction of CO₂ to CO.

The foregoing elucidation of reaction processes together with the recent advances in chemical syntheses of monodisperse NPs and computational methodology, therefore enables design and evaluation or testing of various NP catalysts, making it possible to control specific reaction pathways and to achieve selective electrochemical reactivation of CO₂ into a desired form of carbon, which may, for example, be applied as a feed stock for other hydrocarbon processes or materials. The discoveries herein thus open the door for reducing global CO₂ emissions by removing and/or recycling the CO₂ from industrial and combustion processes into a sustainable feed stock, for more effective and non-polluting utilization of hydrocarbons and carbon-based material and processes.

The invention being thus disclosed, adaptations and variations that tailor NP catalysts for other reductions reactions will be understood by those skilled in the art and are encompassed within the invention, as defined by the following claims.

1. A process for electrocatalytic reduction of CO₂ to CO wherein the reduction is Catalyzed by gold nanoparticles on a conductive support, and the nanoparticles are sized to present a crystalline structure that achieves a stable and efficient reduction.

2. The process of claim 1, wherein the nanoparticles are tuned to present a crystalline structure of the nanoparticles, having lower amount of hydrogen-evolving crystal corner sites and greater amount of CO-converting edge sites, thereby forming a clean CO₂ conversion medium with low formation of by-product species.

3. The process of claim 1, wherein the conductive support is Ketjen carbon.

4. The process of claim 1, wherein the gold nanoparticles are formed with a diameter under 10 nm to effectively tune the catalytic activity of the particles.

5. The process of claim 4, wherein the gold nanoparticles are formed with a diameterof approximately 8 nm.

6. The process of claim 1, carried out in alkaline ionic liquid solution.

7. A catalyst, comprising gold nanoparticles of approximately 8 nm diameter for use in electrocatalytic reduction of carbon dioxide to carbon monoxide.

8. The catalyst of claim 7, wherein the 8 nm Au NPs are polycrystalline with an approximately 4 nm crystallite diameter to provide a near-optimum number of edge sites that are particularly active for CO₂ reduction into CO while providing a low number of corner sites active for the HER.

9. A catalyst, comprising gold nanoparticles of a cuboctahedral crystalline configuration and microcrystal size to present CO-converting edge sites with relatively fewer hydrogen-evolving corner sites, thereby being tuned to form a clean CO₂ conversion medium with low formation of by-product.

10. The catalyst of claim 8, wherein the nanoparticles have a microcrystalline dimension less than nanoparticle diameter that tunes the catalyst to resist poisoning by reduction by-products.
